(19) United States
(12) Patent Application Publication
(10) Pub. No.: US 2025/0079182 A1
(43) Pub. Date: Mar. 6, 2025

(54) Microwave-Enhanced Atomic Layer Etching

(71) Applicant: ASM IP Holding B.V., Almere (NL)

(72) Inventors: Charles Dezelah, Helsinki (FI); Petro Deminskyi, Espoo (FI)

(21) Appl. No.: 18/815,935

(22) Filed: Aug. 27, 2024

Related U.S. Application Data
(60) Provisional application No. 63/535,333, filed on Aug. 30, 2023.

(51) Int. Cl. H01L 21/311; H01L 21/32; H01L 21/3213; H01L 21/67

(52) U.S. Cl. CPC H01L 21/31122; H01L 21/32; H01L 21/32135; H01L 21/32139; H01L 21/67069

(57) ABSTRACT

The current disclosure relates to methods of etching a material. The method comprises method of etching material from a first surface of a material. In the method, the substrate having a first surface of a material is provided into a reaction chamber and an etching step is executed. The etching step comprises etching the first material by executing a plurality of etching cycles. Each etching cycle comprises an etching reactant pulse to expose the substrate to an etching reactant and an anneal pulse to expose the substrate to an anneal. The disclosure further relates to methods of forming a semiconductor device and to a semiconductor device. Further, the disclosure relates to a semiconductor processing system.

### CROSS-REFERENCE TO RELATED APPLICATIONS

This application claims priority to and the benefit of U.S. Provisional Application No. 63/63/535,333, filed Aug. 30, 2024, the entirety of which is incorporated by reference herein.

### FIELD OF INVENTION

The present invention generally relates to a method of atomic layer etching (ALE), and particularly to a method of ALE using an anneal step, such as microwave or infrared radiation, to assist in the reaction of a reactant with a surface targeted for etching.

### BACKGROUND OF THE DISCLOSURE

Atomic layer etching is cyclic, atomic layer-level etching using an etchant that is adsorbed on a target film and reacted with excited species. As compared with conventional etching technology, ALE can perform precise, atomic layer-level continuous etching on a sub-nanometer order to form fine, narrow convex-concave patterns and may be suitable for, e.g., double-patterning processes. Fluorine-based etchants, such as HF, are known to cause integration problems for some applications. Also, the majority of known examples of ALE have one or more steps using exposure of the surface to plasma-generated species. So-called plasma-enhanced ALE (or PE-ALE) is often necessary to provide the reactivity for generating surface reactions needed for producing volatile by-products that allow for film removal. Unfortunately, for many applications, the use of plasma is undesirable, due to the non-uniformity of etching in high aspect ratio features, high potential for anisotropy, as well as the possibility of plasma damage.

The above and any other discussion of problems and solutions in relation to the related art has been included in this disclosure solely for the purpose of providing a context for the present invention, and should not be taken as an admission that any or all of the discussion was known at the time the invention was made.

### SUMMARY OF THE DISCLOSURE

This summary is provided to introduce a selection of concepts in a simplified form. These concepts are described in further detail in the description of example embodiments of the disclosure below. This summary is not intended to identify key features or essential features of the claimed subject matter, nor is it intended to be used to limit the scope of the claimed subject matter.

Various embodiments of the current disclosure relate to a method of etching material from a first surface of a substrate. In one embodiment of the method, a substrate having a first surface of a first material is provided into a reaction chamber and an etching step is executed. The etching step comprises removal of the first material by executing a plurality of etching cycles. Each etching cycle comprises an etching reactant pulse to expose the substrate to an etching reactant and an anneal pulse to expose the substrate to an anneal.

In another aspect, there is disclosed a method for etching comprising: providing a substrate to a reaction chamber, the substrate comprising a first material; executing an etching step that comprises etching the first material by executing a plurality of etching cycles, ones from the plurality of etching cycles comprising an etching reactant pulse, and an anneal pulse, wherein the etching reactant pulse comprises exposing the substrate to an etching reactant and the anneal pulse comprises exposing the substrate to an anneal.

In another aspect, there is disclosed a method for etching comprising: providing a substrate to a reaction chamber, the substrate comprising a first material; executing an etching step that comprises etching the first material by executing a plurality of etching cycles, wherein one or more of the plurality of etching cycles comprises an etching reactant pulse and an anneal pulse, wherein the etching reactant pulse comprises exposing the substrate to an etching reactant and the anneal pulse comprises exposing the substrate to an anneal.

In some embodiments, the substrate comprising a device side and a back side. A first material is positioned on the device side. Further the device side comprises a second material. The etching step comprises selectively etching the first material vis-à-vis the second material.

In some aspects, a method of forming a semiconductor device comprising an etching process according to the current disclosure is disclosed.

In some aspects, a semiconductor device formed by a method comprising an etching process according to the current disclosure is disclosed.

In yet another aspect, a semiconductor processing system for processing a substrate is disclosed. The processing system comprises an etching space constructed and arranged to hold a substrate having a first material, a container for an etching reactant constructed and arranged to contain an etching reactant, and a generator for heating the substrate by polarization and oscillation of water molecules present on the substrate, said generator being disposed outside said etching space and adapted to apply microwaves or infrared radiation to said etching space through a continuous wall of said etching space.

### BRIEF DESCRIPTION OF THE DRAWING FIGURES

The accompanying drawings, which are included to provide a further understanding of the disclosure and constitute a part of this specification, illustrate exemplary embodiments, and together with the description help to explain the principles of the disclosure. In the drawings

FIG. 1 is a schematic presentation of exemplary embodiments of a method according to the current disclosure.

FIG. 2 is a schematic presentation of exemplary embodiment of a method according to the current disclosure.

FIG. 3 is a block diagram of exemplary embodiment of a method according to the current disclosure.

FIG. 4 is a schematic drawing of an embodiment of a semiconductor processing system according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” may include vaporized solid and/or liquid and may be constituted by a single gas or a mixture of gases. In this disclosure, a process gas introduced to a reaction chamber for deposition through a showerhead may be comprised of, consist essentially of, or consist of an etchant gas and an additive gas. The additive gas typically includes a dilution gas for diluting the etchant gas and reacting with the etchant gas when in an excited state. The etchant gas can be introduced with a carrier gas such as a noble gas. Also, a gas other than the process gas, i.e., a gas introduced without passing through the showerhead, may be used for, e.g., sealing the reaction space, which includes a seal gas such as a noble gas.

In some embodiments, the term “etchant reactant” refers generally to at least one compound that participates in an etching reaction that etches a target layer on a substrate, and particularly to at least one compound that deposits on the target layer in an excited state and etches the target layer when being activated by an anneal. The term “etchant precursor” refers to at least one compound that contributes to deposition of the etchant film, activation of the etchant film, or catalyzes an etching reaction by components of the etchant film. The dilution gas and/or carrier gas can serve as an “etchant precursor”. The term “carrier gas” refers to an inert or inactive gas in a non-excited state which carries an etchant precursor to the reaction space in a mixed state and enters the reaction space as a mixed gas including the etchant precursor. In the current disclosure, in some embodiments, the “etchant reactant”, the “etchant precursor” and the “anneal pulse” can each independently act as surface modifiers or etchants, with the limitation that each etching cycle has at least one of a surface modifier and etchant.

Further, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Additionally, the terms “constituted by” and “having” refer independently to “typically or broadly comprising”, “comprising”, “consisting essentially of”, or “consisting of” in some embodiments. Further, an article “a” or “an” refers to a species or a genus including multiple species. In this disclosure, any defined meanings do not necessarily exclude ordinary and customary meanings in some embodiments.

In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation process or sequence, and/or functions or purposes of the adjacent films or layers.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The embodiments will be explained with respect to preferred embodiments. However, the present invention is not limited to the preferred embodiments.

Some embodiments provide a method of etching material from a first surface of a material. In the method, the substrate having a first surface of a material is provided into a reaction chamber and an etching step is executed. The etching step comprises etching the first material by executing a plurality of etching cycles. Each etching cycle comprises an etching reactant pulse to expose the substrate to an etching reactant and an anneal pulse to expose the substrate to an anneal. In this disclosure, the term “anneal” refers to electromagnetic radiation. The anneal is used for activation of either the precursors, substrate or surface sites during the etching cycle. In some embodiments, the electromagnetic radiation is microwave radiation. In this embodiment, in the etching cycle the term anneal refers to microwave-enhanced or microwave-assisted etching. In some embodiments, the electromagnetic radiation is infrared radiation. In some embodiments, anneal does not include a thermal treatment. In some embodiments, anneal does include thermal treatment. In this embodiment, in the etching cycle the term anneal refers to infrared-enhanced or infrared-assisted etching. Both microwave and infrared -assisted and -enhanced etching can be defined as methods that comprise radiation exposure to a substrate to activate the surface to enable chemical reactions, where exposure occurs as described in the pulsing sequences defined later in the current disclosure.

In one embodiment there is no etching reactant in the reaction chamber during the anneal pulse. The anneal pulse is executed after the substrate is exposed to the etching reactant and optionally the chamber has been purged after the etching reactant has been fed into the reaction chamber.

In one embodiment, the substrate is exposed to the anneal pulse during the etching reactant pulse.

Some embodiments provide a method according to the previous disclosure, wherein the substrate comprises a device side and a back side. The first material is positioned on the device side. The device side further comprises a second material. The etching step comprises selectively etching the first material vis-à-vis the second material.

In some embodiments, the etching cycle further comprises an etching precursor pulse. The etching precursor pulse comprises exposing the substrate to an etching precursor.

In some embodiments, substrate is first exposed to an etching reactant, then the chamber is purged before an anneal pulse. After this the chamber is purged before exposing the substrate to an etching precursor, and finally the chamber is purged for a third time.

In some embodiments, the substrate is first exposed to an etching reactant, then the chamber is purged before exposing the substrate to an etching precursor. After this the chamber is purged before an anneal pulse, and finally the chamber is purged for a third time.

In some embodiments, the substrate is first exposed to an etching reactant, then the chamber is purged before an anneal pulse. After this the chamber is purged before exposing the substrate to an etching precursor, and finally the chamber is purged for a third time before a second anneal pulse.

In some embodiments, the substrate is simultaneously or a least partially overlappingly exposed to an etching reactant and anneal pulse. After this the chamber is purged before exposing the substrate to an etching precursor.

In some embodiments, the substrate is first exposed to an etching reactant. Then the reaction chamber is purged before simultaneously or a least partially overlappingly exposing the substrate to an etching precursor and anneal pulse.

In some embodiments, the substrate is first simultaneously or a least partially overlappingly exposed to an etching reactant and anneal pulse. Then the reaction chamber is purged before simultaneously or a least partially overlappingly exposing the substrate to an etching precursor and anneal pulse.

In some embodiments, the substrate is first exposed to an etching reactant, then the chamber is purged before an anneal pulse. Then the reaction chamber is purged before simultaneously or a least partially overlappingly exposing the substrate to an etching precursor and anneal pulse.

In some embodiments, the substrate is first simultaneously or a least partially overlappingly exposed to an etching reactant and anneal pulse. Then the reaction chamber is purged before exposing the substrate to an etching precursor. Finally, the reaction chamber is purged before a final anneal pulse.

In some embodiments, the anneal pulse occurs at least partially simultaneously with the etching precursor pulse and/or the etching reactant pulse. The effect of having the anneal pulse is that some precursors/etchants may need activation prior to encountering the substrate surface to react appropriately. Other precursors can react well at the surface without the anneal, but need extra energy after surface-reaction to effectively produce the by-products needed for etching.

In some embodiments, the anneal pulse occurs at least partially simultaneously with the etching reactant pulse.

For a surface to be etched, the surface needs to be first modified and then exposed to an etchant. In the current disclosure, in one embodiment, the etching reactant acts a surface modifier. In one embodiment, the etching reactant acts as an etchant. In one embodiment, the etching precursor acts a surface modifier. In one embodiment, the etching precursor acts as an etchant. In one embodiment, the anneal pulse acts as a surface modifier. In one embodiment, the anneal pulse acts as an etchant.

As mentioned above, the anneal pulse, in other words electromagnetic radiation can happen either between the reactant and/or precursor pulse, during the reactant and/or precursor pulse, or to activate/deactivate the substrate surface. When the radiation happens between the reactant and precursor pulses, the substrate is heated which can in some embodiments, lead to the substrate heating to the temperature desired for material etching in an atomic layer etching process. In some embodiments, the heating leads to material on the substrate to be heated, which can lead to the film heating to the temperature desired for material etching in an atomic layer etching process. In one embodiment, the already-deposited material can anneal by exposure to the radiation, which can lead to a change in material properties that can create favorable conditions for its further etching. In one embodiment, the surface sites are re-arranged due to a dipole activation by the radiation. Under specific conditions surface sites can be re-arranged in a way which promotes controllable atomic layer etching. By “surface sites”, it is meant a ligand attached to the surface or top layer of material that should be etched.

In the embodiments in which the radiation happens during the reactant and/or precursor pulse, the precursor can be activated in gas phase in the reactor chamber. In other words, the reactant or precursor can get additional reactivity in a gas phase due to a radiation. This can happen due to a dipole moment for a reactant or precursor. The additional reactivity can create conditions promoting atomic layer etching. In one embodiment, the reactant or precursor can be activated in a gas phase near the desired surface. The reactant or precursor can get additional reactivity near the surface due to radiation and thus heating of a material on a substrate. In one embodiment, the reactant or precursor interaction with the substrate and its higher reactivity is due to a dipole moment both for the substrate and reactant or precursor molecule or one of each. This can cause additional activation between precursor molecule and the desired surface causing higher reactivity, which can promote controllable etching.

In the embodiments where the surface activation/de-activation leads to selective atomic layer etching, there are two possible ways in which radiation can impact atomic layer etching. In one embodiment, the surface sites are re-arranged by microwave irradiation, which leads to surface de-activation. Under specific conditions, surface sites can be re-arranged in a way which inhibits controllable ALE. While one material can be de-activated, another one can still remain activated leading to selective ALE. In one embodiment, the etching is based on the surface activation for one material, while the reactivity for another one remains similar. This could lead to a different etching rate, leading to a controllable thickness for various materials.

In some embodiments, the substrates have a dipole moment. In some embodiments the deposited material has a dipole moment. In some embodiment, the etching reactants have dipole moment. This will increase the reactant reactivity under the microwave radiation depending on reactant selection. This is caused by reactant symmetry which affects the distribution of charges within a molecule and, consequently, its dipole moment. In symmetrical molecules, the dipole moment of individual bonds or functional groups balance each other resulting in a low dipole moment and thus, low dielectric constant.

In some embodiments, the reactant selection can be made, based on the dielectric constant of the reactant depending on the wanted outcome which can be, for example: a) increase reactivity in the gas phase; b) increase reactivity near the surface due to the precursors friction with the surface; or c) increase reactivity in the gas phase and due to the interaction with the surface.

In some embodiments, a reactant with low dielectric constant can be selected from the group consisting of Ar, GeCl₄, TiCl₄, TEAl, AlBr₄, BI₃, allyl iodide, allyl bromide, allyl chloride, and methylene chloride. In some embodiments, a reactant with high dielectric constant can be selected from the group consisting of NH₃, and SbBr₃. In some embodiments, a reactant with an ultra-high dielectric constant can be selected from the group consisting of hydrazine, H₂O, and D₂O.

In some embodiments, ones from the plurality of etching cycles further comprise one or more purges. In this context, the term “purge” may refer to the act of removing any unwanted and unreacted products and by-products, and any remaining gas(es) from the reaction chamber and for stabilizing the reaction space and getting ready for the next step. In one embodiment, the chamber is purged between exposing the substrate to the etching reactant and the etching precursor. In one embodiment, the chamber is purged between exposing the substrate to the etching precursor and the anneal pulse. In one embodiment, the chamber is purged between exposing the substrate to the etching reactant and the etching precursor, as well as between exposing the substrate to the etching precursor and the anneal pulse. In one embodiment, the chamber is purged between exposing the substrate to the etching reactant and the anneal pulse.

In some embodiments, the first material comprises a material selected from the group consisting of metal oxide, elemental metal and metal nitride. In some embodiments, the first material is a metal oxide selected from the group consisting of MgO, MgAlₓOy, CaO, SrTiO₃, BaTiO₃, Sc₂O₃, Y₂O₃, La₂O₃, Ce₂O₃, CeO₂, Pr₂O₃, Nd₂O₃, SmO, Sm₂O₃, Gd₂O₃, Tb₂O₃, Dy₂O₃, Ho₂O₃, Er₂O₃, Yb₂O₃, Lu₂O₃, TiO₂, ZrO₂, HfO₂, ZrSiO₄, HfSiO₄, V₂O₃, VO₂, V₂O₅, Nb₂O₅, Ta₂O₅, Cr₂O₃, MoO₃, WO₃, MnO, Mn₃O₄, Mn₂O₃, MnO₂, MnO₃, Mn₂O₇, FeO, Fe₂O₃, RuO₂, CoO, Co₂O₃, Co₃O₄, NiO, Cu₂O, CuO, ZnO, Al₂O₃, Ga₂O₃, InO, In₂O₃, SiO₂, GeO₂, SnO, SnO₂, PbO, PbO₂, Sb₂O₃, Sb₂O₅, Bi₂O₃ and TeO₂. In some embodiments, the first material is an elemental metal selected from the group consisting of Ti, Ta, Cr, Mo, W, Re, Fe, Ru, Os, Co, Rh, Ir, Ni, Pd, Pt, Cu, Ag, Au, Al, Si, Ge, Sn and Sb. In some embodiments, the first material is a metal nitride selected from the group consisting of MgN, ScN, YN, LaN, TiN, ZrN, HfN, VN, VNₓ, NbN, Nb₃N₅, NbNₓ, TaN, Ta₃N₅, TaNₓ, CrNₓ, MoN, Mo₂N, MoNₓ, WN, W₂N, WNₓ, ReNₓ, FeNₓ, RuAlₓN_{y}, RuSiₓN_{y}, RuTaₓN_{y}, RuTiₓN_{y}, CoNₓ, Ni₃N, NiNₓ, Cu₃N, CuNₓ, BN, AlN, GaN, InN, SiN, Si₃N₄, SiNₓ and SnNₓ.

In some embodiments, the etching precursor comprises an oxidizing agent or a chlorinating agent. In some embodiments the oxidizing agent is selected from the group consisting of ozone, oxygen, water, nitrous oxide and hydrogen peroxide. In some embodiments, the chlorinating agent is selected from the group consisting of phosphorous pentachloride, phosphorous trichloride, phosphoryl chloride, thionyl chloride, sulfuryl chloride, disulfur dichloride, acetyl chloride, oxalyl chloride, N-chlorosuccinimide, and t-butyl hypochlorite.

In some embodiments, the chlorinating agent comprises a C-Cl bond. In some embodiments, the chlorinating agent is an acyl halide. In some embodiments, the chlorinating agent is oxalyl chloride. In some embodiments, the chlorinating agent is acetyl chloride.

In some embodiments, the chlorinating agent comprises a S-Cl bond. In some embodiments, the chlorinating agent is thionyl chloride. In some embodiments, the chlorinating agent is sulfuryl chloride. In some embodiments, the chlorinating agent is an alkyl sulfonyl chloride. In some embodiments, the chlorinating agent is disulfur dichloride, S₂Cl₂. In some embodiments, the chlorinating agent is sulfur dichloride, SCl₂.

In some embodiments, the chlorinating agent comprises a P-Cl bond. In some embodiments, the chlorinating agent is PCl₃. In some embodiments, the chlorinating agent is PCl₅. In some embodiments, the chlorinating agent is POCl₃. In some embodiments, the chlorinating agent is a dialkylphosphinic chloride (e.g., R₂POCl, R=alkyl). In some embodiments, the chlorinating agent is a diarylphosphinic chloride (e.g., R₂POCl, R=aryl). In some embodiments, the chlorinating agent is an alkylphosphonic dichloride (e.g., RPOCl₂, R=alkyl). In some embodiments, the chlorinating agent is an arylphosphonic dichloride (e.g., RPOCl₂, R=aryl).

In some embodiments, the chlorinating agent comprises a N-Cl bond. In some embodiments, the chlorinating agent is N-chlorosuccinimide.

In some embodiments, the chlorinating agent comprises a O-Cl bond. In some embodiments, the chlorinating agent is an alkyl hypochlorite. In some embodiments, the chlorinating agent is tert-butyl hypochlorite.

In some embodiments, the etching reactant comprises an agent selected from the group consisting of an alkylating agent, cyclopentadiene, alkylcyclopentadiene, trimethylsilylcyclopentadiene, N,N′-dialkylcarbodiimide, dialkylamines, alcohols, and halogenating agents. In some embodiments the alkylating agent is selected from the group consisting of alkyl triflate, such as ethyl triflate, dialkyl carbonates, such as diethyl carbonate, dialkyl sulfates, such as dimethyl sulfate, trimethylsilyldiazomethane, alkyl halides, such as diiodomethane, t-butyl iodide, ethyl iodide, 1-chlorohexane, 1-bromobutane, benzyl bromide, and benzyl iodide, aryl halides, such as bromobenzene and iodobenzene, allyl halides 3-bromo-1-propene, 3-iodo-1-propene and 1-bromo-2-butene, and metal alkyl compounds, such as trimethylaluminum, triethylaluminum, diethylzinc and trimethylgallium. In some embodiments, the dialkylamine is selected from the group consisting of dimethylamine, diethylamine, ethylmethylamine, bis(trimethylsilyl)amine, and diisopropylamine. In some embodiments, the alcohol is selected from the group consisting of methanol, ethanol, isopropanol, tert-butanol, tert-pentanol, trimethylsilanol, and triethylsilanol.

In some embodiments, the halogenation agent is selected from the list of chlorination agents as listed above in the description.

In some embodiments, the anneal pulse comprises a microwave pulse or an infrared pulse. The purpose of the anneal pulse is to assist in the reaction of a reactant with a surface of the first material, or to aid in the formation and/or removal of a volatile by-product and thereby driving the etching reaction and enabling atomic layer etching process to work under conditions where it would otherwise be kinetically slow or thermodynamically disfavored. The reactant may be, for example, a ligand, conversion agent or etchant of the etching precursor of etching reactant.

In some embodiments, the anneal exposure is alternated with the self-limiting reaction of a single reactant. In some embodiments the anneal exposure is alternated with the self-limiting reactions of two or more reactants that are applied sequentially. In some embodiments, the anneal exposure is concurrent with the introduction of one reactant within a process where one or more other reactants are applied sequentially, each of which provides a self-limiting reaction within an atomic layer etching process. In some embodiments, the anneal exposure is concurrent with the separate introduction of multiple reactants, each of which are applied sequentially to provide self-limiting reactions within an atomic layer etching process.

In some embodiments, the microwaves are applied at a frequency of 0.3-300 GHz, for example, 0.5-100 GHz, such as 1-20 GHz, or 2-5 GHz.

In some embodiments, the infrared is applied at a wavelength 0.7-1000 μm, for example, 1-800 μm, such as 20-600 μm, or 30-500 μm.

In some embodiments, the etching cycle is repeated for example at least one time, for example at least two times, for example at least ten times, for example at least twenty times, for example at least fifty times, for example at least one hundred times, for example at least five hundred times, for example at least one thousand times, for example, at least five thousand times.

In some embodiments, the etching cycle is repeated until the first material is removed from the substrate. In some embodiments, the etching cycle is repeated until a predetermined thickness of the first material is removed from the substrate. The predetermined value can be, for example, 0.1 to 20 nm, for example 0.5 to 15 nm, for example, 1.5 to 10 nm, for example 2 to 7 nm, such as about 0.5 nm, such as about 1 nm, such as about 2 nm.

In some embodiments, the second material comprises a polymer.

In some embodiments, the polymer has a dielectric constant of 4.1 or less. The difference in the dielectric constant of the second material and the first material allows the second material to not be heated during the anneal step and therefore not be etched from the substrate. In some embodiments, the polymer is selected from the group consisting of polytetrafluoroethylene, polyvinylidene fluoride, poly(isobutylethylene), polyvinyl fluoride, poly(ethylene), poly(isobutene), poly(propylene), poly(1-butene), poly(1,4-butadiene), poly(2-methylstyrene), poly(4-methylstyrene), polystyrene, poly(propylene glycol), polytetrahydrofuran, poly(chlorotrifluoroethylene), poly(cyclohexyl methacrylate), poly(1,4-phenyl ether), poly(4-chlorostyrene), poly(isobutyl methacrylate), poly(butyl methacrylate), poly(2-chlorostyrene), poly(2,6-diphenyl-p-phenylene oxide), poly(ethyl methacrylate), polyvinylidene chloride, poly(caprolactone), polyacetal, poly(methylene oxide), poly(Bisphenol A carbonate), poly(2-chloro-p-xylylene), poly(methyl methacrylate), poly(thio-1,4-phenylene), polyvinyl chloride, poly(acrylonitrile), poly[(tetramethylene terephthalate), poly(vinyl acetate), poly(ethylene terephthalate), polyhexamethylene sebacamide, polyhexamethylene adipamide, polyimide, polyamide and poly(caprolactam).

Some embodiments provide a method of forming a semiconductor device comprising an etching process according to any one of the preceding claims.

Some embodiments provide a semiconductor device formed by a method comprising an etching process according to the current disclosure.

Some embodiments provide a semiconductor processing system for processing a substrate. The processing system comprises an etching space constructed and arranged to hold a substrate having a first material, a container for an etching reactant constructed and arranged to contain an etching reactant, and a generator for heating the substrate by polarization and oscillation of water molecules present on the substrate. The generator is disposed outside said etching space and adapted to apply microwaves or infrared radiation to the etching space through a continuous wall of said etching space.

In some embodiments, the generator may be located at any side of the etching space. In one embodiment, the generator is located at the top part of the etching space. In one embodiment, the generator is located at the side of the etching space. In one embodiment, the generator surrounds the etching space. In one embodiment, the generator can be moved and locked in position at any location around the etching space to adjust the direction of microwave or infrared radiation towards the substrate. As such, the generator directs the radiation on a surface of the substrate.

In some embodiments, the generator is positioned in a separate chamber such that the substrate is first exposed to an etching reactant in the etching space. Then the substrate is moved to a second chamber to be exposed to the microwave or infrared radiation.

In some embodiments, the substrate additionally comprises a second material.

In some embodiments the semiconductor processing system further comprises a container for an etching precursor constructed and arranged to contain an etching precursor.

In some embodiments, the second material is not removed from the surface of the substrate.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

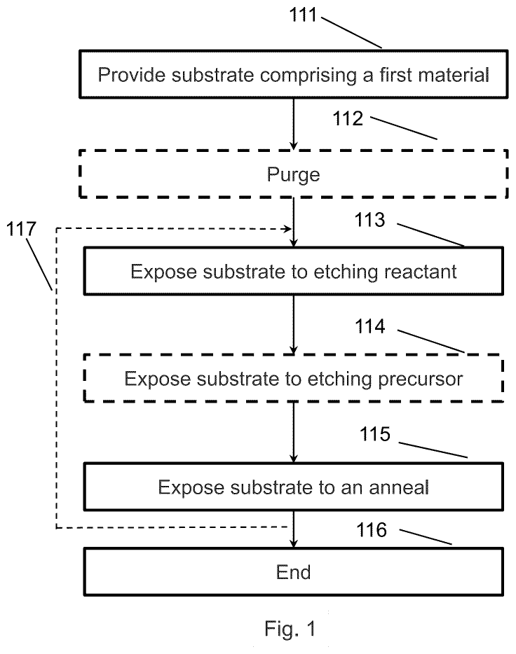

In some embodiments, the process may be performed as illustrated in FIG. 1 which shows a flow chart of an atomic layer etching (ALE). In step 111, a film of a first material is deposited on a surface of a substrate by any suitable deposition method, such as plasma-enhanced atomic layer deposition, plasma-enhanced chemical vapor deposition, thermal atomic layer deposition or thermal chemical vapor deposition, which can preferably perform conformal deposition. Step 112 is an optional purging step to purge the reaction space. In other words, the purging step rinses the reaction space from any previously fed gasses or reactants. After step 112, in step 113, the deposited film is exposed to an etching reactant. During this step the etching reactant reacts with the surface of the deposited film. In step 114, the substrate is optionally exposed to an etching precursor. In step 115, an anneal pulse is applied to the reaction space. During this step either a pulse of microwave or infrared radiation is applied to the substrate. Steps 113, 114 and 115 together form an etching cycle. Steps 113, 114 and 115 can be performed in any order. In some embodiments, the anneal pulse 115 can follow both steps 113 and 114. The etching cycle removes at least part of the first material. The etching cycle is repeated, 117, as many times as is needed. In some embodiments the etching cycle is repeated for example 10 times, for example 20 times, for example 50 times, or for example 100 times. After the first material is etched either completely or to a wanted thickness, the process is ended 116.

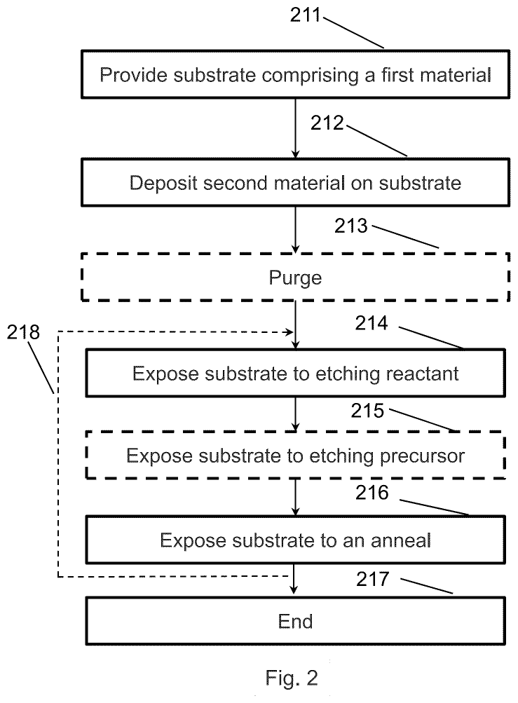

In some embodiments, the process may be performed as illustrated in FIG. 2 which shows a flow chart of a selective atomic layer etching. In step 211, a film of a first material is deposited on a surface of a substrate by any suitable deposition method which can preferably perform conformal deposition. In step 212, a film of a second material is deposited on the substrate. The second material is preferably a polymer with a low dielectric constant. Step 213 is an optional purging step to purge the reaction space. In other words the purging step rinses the reaction space from any previously fed gasses or reactants. After step 213, in step 214, the deposited film is exposed to an etching reactant. During this step, the etching reactant reacts with the surface of the deposited film. In step 215, the substrate is optionally exposed to an etching precursor. In step 216, an anneal pulse is applied to the reaction space. During this step, either a pulse of microwave or infrared radiation is applied to the substrate. Steps 214, 215 and 216 together form an etching cycle. The etching cycle removes at least part of the first material without removing substantial amount of the second material. The etching cycle is repeated, 218, as many times as is needed. In some embodiments the etching cycle is repeated for example 10 times, for example 20 times, for example 50 times, or for example 100 times. After the first material is etched either completely or to a wanted thickness, the process is ended 217.

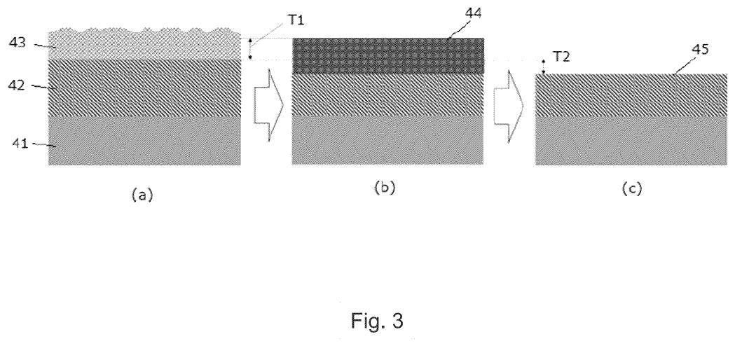

FIG. 3 illustrates a schematic drawing of one cycle of an etching process according to an embodiment of the present invention, wherein (a) represents a deposition step, (b) represents a pre-etching step, and (c) represents an etching step. Prior to the deposition step (step (a)), a substrate 41 (e.g., a silicon wafer or other semiconductor wafer), on which a first material 42 is formed, is provided in a reaction space. In the deposition step, an etchant film 43 is deposited on the target layer 42 at a thickness no less than a saturation thickness T1, wherein the etchant film 43 and the first material layer 42 are in contact with each other. The saturation thickness T1 is defined as a thickness, a portion of the etchant film beyond which does not contribute to etching of the first material layer, i.e., an etched quantity of the first material layer does not increase even if the thickness of the etchant film further increases beyond the saturation thickness T1. In the pre-etching step (step (b)), the etchant film 43 is exposed to an anneal, such as microwave or infrared radiation, thereby etching the etchant film, generating gaseous components therefrom, and removing the top portion of the etchant film 43 above the saturation thickness T1.

When the etching of the etchant film 43 progresses and the etchant film 43 is etched to the saturation thickness T1, gaseous components from the etchant film 43 simultaneously generate gaseous components from a portion of the first material layer 42 having a depth T2.

The boundary region 44 is comprised of a boundary region of the etchant film 43 having the saturation thickness T1 and a boundary region of the first material layer 42 having a depth T2. The total thickness of the boundary region (T1+T2) may depend on the energy in the anneal and the pressure of the reaction space. The boundary region 44 may be composed of an intermediate constituted by mixed components.

In the etching step (step (c)), the boundary region or intermediate layer 44 is removed as gaseous components, wherein the target layer 42 is etched by the depth T2 to obtain an etched first material layer 45. It should be noted that although steps (b) and (c) are separately shown for an easy understanding of the principle of the steps, these steps rather concurrently occur.

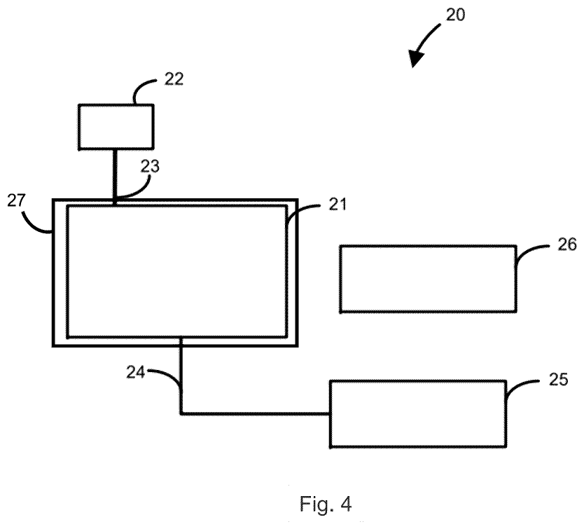

FIG. 4 illustrates an exemplary embodiment of a semiconductor processing system 200 according to the current disclosure. As a schematic representation of a semiconductor processing system 20, many components have been omitted for simplicity of illustration, and such components may include, for example, various inlets, outlets, valves, manifolds, purifiers, heaters, containers, vents, and/or bypasses.

The semiconductor processing system 20 comprises an etching space 21, an etching reactant reservoir 22 for holding etching reactant, an inlet 23 for providing an etching reactant into the etching space 21, and an outlet 24 for removing etching reactant from the etching space 21.

The etching space 21 may be a reaction chamber. The etching space 21 may be configured and arranged for holding one substrate. Alternatively, the etching space 21 may be configured and arranged for holding two or more substrates.

The reactant reservoir 22 is configured and arranged to hold an etching reactant according to the current disclosure. In some embodiments, the semiconductor processing system 20 comprises a second or a further reactant or precursor reservoir (not depicted). For example, additional oxidizing or other accessory agents may be stored in a second reactant reservoir, and an accessory agent can be mixed with the etching reactant as needed.

Used etching reactant may be removed from the etching space 21 through an outlet 24. The used etching liquid may be collected in a disposal reservoir 25.

The embodiment of a semiconductor processing system of FIG. 4 additionally comprises a generator 27 for heating the substrate by polarization and oscillation of water molecules present on the substrate. The generator 27 is located outside the etching space 21 and adapted to apply microwaves or infrared radiation to said etching space through a continuous wall of the etching space 21.

The embodiment of a semiconductor processing system of FIG. 4 additionally comprises a controller 26. The controller 26 includes electronic circuitry and software to selectively operate valves, manifolds, heaters, pumps and other components included in the semiconductor processing system 20. Such circuitry and components operate to provide liquids, regulate temperature, pressure etc. to provide proper operation of the semiconductor processing system 20. Controller 26 can include modules such as a software or hardware component, which performs certain tasks. A module may be configured to reside on the addressable storage medium of the control system and be configured to execute one or more processes.

During operation of semiconductor processing system 20, one or more substrates, such as semiconductor wafers (not illustrated), are transferred to etching space 21. Depending on the configuration of the system 20, etching liquid is provided into the etching space 21, or the substrate(s) make contact with etching liquid previously present in the etching space 21.

Although certain embodiments and examples are disclosed herein, it will be understood by those skilled in the art that the disclosed methods and systems extend beyond the specifically disclosed embodiments and include all novel and nonobvious combinations and sub-combinations of the various processes, systems, and configurations, as well as any and all equivalents thereof. It is to be understood that the methods and/or systems described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods and systems of disclosure are not to be interpreted as reflecting an intention that the claimed disclosure requires more features than are expressly recited in each claim. Rather, as the following claims reflect, inventive aspects lie in less than all features of single foregoing disclosed aspects, embodiments, and configurations. Thus, the following claims are hereby incorporated into this Detailed Description, with each claim standing on its own as a separate preferred embodiment of the disclosure.

1. A method for etching comprising:
providing a substrate to a reaction chamber, the substrate comprising a first material;
executing an etching step that comprises etching the first material by executing a plurality of etching cycles, ones from the plurality of etching cycles comprising an etching reactant pulse, and an anneal pulse;
wherein
the etching reactant pulse comprises exposing the substrate to an etching reactant; and
the anneal pulse comprises exposing the substrate to an anneal.

2. The method according to claim 1,
wherein the substrate comprises a device side and a back side;
wherein the first material is positioned on the device side;
wherein the device side further comprises a second material; and,
wherein the etching step comprises selectively etching the first material vis-à-vis the second material.

3. The method according to claim 2, wherein the second material comprises a polymer.

4. The method according to claim 3, wherein the polymer has a dielectric constant of 4.1 or less.

5. The method according to claim 1, the etching cycle further comprising an etching precursor pulse, wherein the etching precursor pulse comprises exposing the substrate to an etching precursor.

6. The method according to claim 5, wherein the etching precursor comprises an oxidizing agent or chlorinating agent.

7. The method according to claim 5, wherein the anneal pulse occurs at least partially simultaneously with the etching precursor pulse.

8. The method according to claim 1, wherein the anneal pulse occurs at least partially simultaneously with the etching reactant pulse.

9. The method according to claim 1, wherein ones from the plurality of etching cycles further comprise one or more purges.

10. The method according to claim 1, wherein the first material comprises metal oxide, elemental metal or metal nitride.

11. The method according to claim 1, wherein the etching reactant comprises an agent selected from the group consisting of an alkylating agent, cyclopentadiene, alkylcyclopentadiene, trimethylsilylcyclopentadiene, N,N′-dialkylcarbodiimide, dialkylamines, alcohols, and halogenating agents.

12. The method according to claim 1, wherein the anneal pulse comprises a microwave pulse or an infrared pulse.

13. The method according to claim 12, wherein the microwave pulse is applied at a frequency of 0.3-300 GHz.

14. The method according to claim 12, wherein the infrared pulse is applied at a wavelength 1-800 μm.

15. The method according to claim 1, wherein the plurality of etching cycles are repeated until the first material is removed from the substrate.

16. A semiconductor device formed by a method according to claim 1.

17. A semiconductor processing system for processing a substrate, the processing system comprising:
an etching space constructed and arranged to hold a substrate having a first material;
a container for an etching reactant constructed and arranged to contain an etching reactant; and
a generator for heating the substrate by polarization and oscillation of water molecules present on the substrate, said generator being disposed outside said etching space and adapted to apply microwaves or infrared radiation to said etching space through a continuous wall of said etching space.

18. The semiconductor processing system according to claim 17, wherein the substrate further comprises a second material.
